(19) United States
(12) Patent Application Publication
(10) Pub. No.: US 2024/0386072 A1
(43) Pub. Date: Nov. 21, 2024

(54) SHIFTER IMPLEMENTED CIRCULANT PERMUTATION MATRIX OPERATIONS

(71) Applicant: EDGECORTIX INC., Tokyo (JP)

(72) Inventors: Kunihiko IETOMI, Kanagawa (JP); Nikolay NEZ, Tokyo (JP); Oleg KHAVIN, Tokyo (JP); Sakyasingha DASGUPTA, Tokyo (JP)

(21) Appl. No.: 18/657,786

(22) Filed: May 8, 2024

Related U.S. Application Data
(60) Provisional application No. 63/502,417, filed on May 16, 2023.

(51) Int. Cl. G06F 17/16

(52) U.S. Cl. CPC G06F 17/16

(57) ABSTRACT

Shifter implemented circulant permutation matrix operations are realized by an integrated circuit including a forward shifter configured to shift forward each sequential value of a target segment by a shift amount to produce a forward-shifted partial segment, a reverse shifter configured to shift in reverse each sequential value of the target segment by a reverse shift value equal to a segment length minus the shift amount to produce a reverse-shifted partial target segment, a combiner configured to combine the forward-shifted partial target segment with the reverse-shifted partial target segment according to the shift amount and the segment length to produce a shifted target segment, and a mask selector configured to select at least one of a merge mask corresponding to the shift amount and the segment length and a filter mask corresponding to the segment length.

### CROSS-REFERENCE TO RELATED APPLICATIONS

The present application claims priority to Provisional Application No. 63/502,417, filed May 16, 2023, the contents of which are hereby incorporated by reference herein in their entirety.

### BACKGROUND

Wireless data communication has become ubiquitous in modern society. As digital data transmission became more prevalent, the utility of reliable and error-free communication over noisy wireless channels became apparent. This led to the creation of forward error correction (FEC) codes. FEC codes are mathematical algorithms used to add redundant information to transmitted data, allowing the receiver to correct errors that may occur during transmission. FEC codes became essential as wireless communication systems expanded, especially with the advent of mobile phones and data-intensive applications. Without FEC, wireless data transmission would suffer from higher error rates, leading to data corruption and costly retransmissions. FEC codes, like Low-Density Parity-Check (LDPC) codes, are integral components of modern wireless technologies, improving data integrity and reducing the impact of channel impairments, making wireless communication reliable and efficient.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a system for Low-Density Parity-Check (LDPC) data transmission, according to at least one embodiment of the present invention.

FIG. 2 is a schematic diagram of an integrated circuit encoder for LDPC data encoding, according to at least one embodiment of the present invention.

FIG. 3 is a schematic diagram of an integrated circuit decoder for LDPC data decoding, according to at least one embodiment of the present invention.

FIG. 4 is a schematic diagram of a processor utilizing shifter implemented circulant permutation matrix operations, according to at least some embodiments of the present invention.

FIG. 5 is a schematic diagram of circular shifter utilizing shifter implemented circulant permutation matrix operations, according to at least some embodiments of the present invention.

FIG. 6A is a diagram of original positions of a target segment, according to at least one embodiment of the present invention.

FIG. 6B is a diagram of a shifted target segment having a segment length of 3 and shifted by 2, according to at least one embodiment of the present invention.

FIG. 6C is a diagram of a shifted target segment having a segment length of 3 and shifted by 2, according to at least one embodiment of the present invention.

FIG. 6D is a diagram of a shifted target segment having a segment length of 3 and shifted by 2, according to at least one embodiment of the present invention.

FIG. 6E is a diagram of a shifted target segment having a segment length of 3 and shifted by 2, according to at least one embodiment of the present invention.

FIG. 7 is an operational flow for LDPC data decoding utilizing paged buffering, according to at least some embodiments of the present invention.

FIG. 8 is an operational flow for data probability value segment decoding utilizing shifter implemented circulant permutation matrix operations, according to at least one embodiment of the present invention.

FIG. 9 is an operational flow for applying a shifter implemented circulant permutation matrix operation, according to at least one embodiment of the present invention.

FIG. 10 is a diagram of a data segment undergoing a shifter implemented circulant permutation matrix operation, according to at least one embodiment of the present invention.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. In addition, the present disclosure may repeat reference numerals and/or letters in the various examples. This repetition is for the purpose of simplicity and clarity and does not in itself dictate a relationship between the various embodiments and/or configurations discussed.

Efficient decoding of data encoded with FEC codes plays a crucial role in the spread of wireless communication to the vast and diverse array of connected devices, many of which have limited power and processing capabilities, such as IoT (Internet of Things) devices.

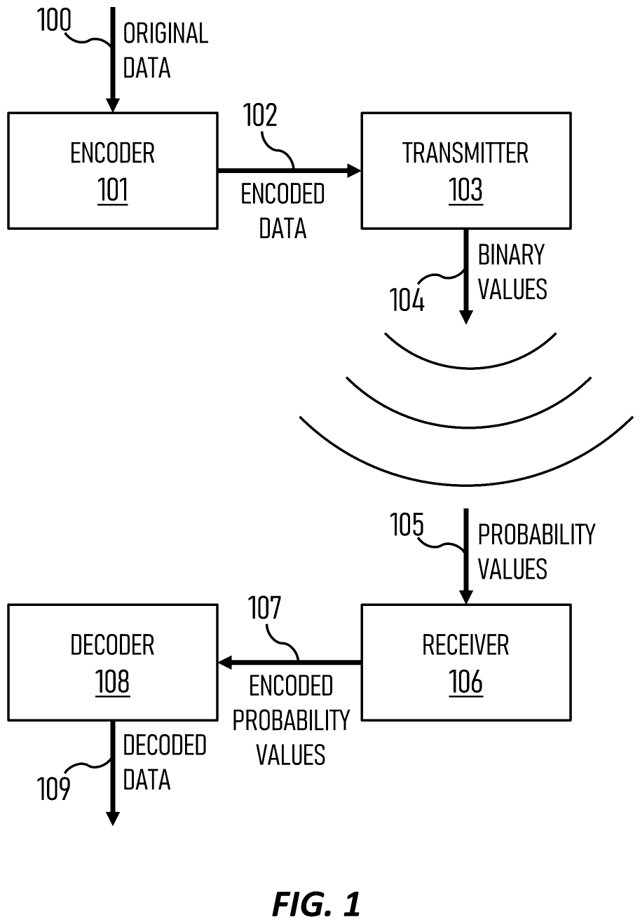

FIG. 1 is a schematic diagram of a system for Low-Density Parity-Check (LDPC) data transmission, according to at least one embodiment of the present invention. The system includes an encoder 101, a transmitter 103, a receiver 106, and a decoder 108. In at least some embodiments, encoder 101 and transmitter 103 are parts of a single device, such as a transmission tower of a radio access network. In at least some embodiments, receiver 106 and decoder 108 are parts of a single device, such as a smartphone in communication with a radio access network. In at least some embodiments, such single devices have an encoder, a transmitter, a receiver, and a decoder, enabling bi-directional communication. In FIG. 1, because transmitter 103 is in direct communication with receiver 106, encoder 101 and transmitter 103 would not be part of the same device as receiver 106 and decoder 108.

Encoder 101 is configured to receive original data 100, and to transmit encoded data 102 to transmitter 103. In at least some embodiments, encoder 101 is configured to receive original data 100 in blocks of one or more predetermined lengths. In at least some embodiments, encoder 101 is configured to apply FEC encoding to original data 100 to produce encoded data 102. In at least some embodiments, encoder 101 is configured to apply LDPC encoding to original data 100 to produce encoded data 102. In at least some embodiments, encoder 101 is an integrated circuit, such as a Field-Programmable Gate Array (FPGA), Application Specific Integrated Circuit (ASIC), etc. In at least some embodiments, encoder 101 is a computer having a processor and a memory storing instructions for execution by the processor.

Transmitter 103 is configured to receive encoded data 102 from encoder 101, and to transmit binary values 104 of encoded data 102 to receiver 106 through wireless communication. In at least some embodiments, transmitter 103 is configured to transmit encoded data 102 in blocks of one or more predetermined lengths. In at least some embodiments, transmitter 103 is configured to transmit binary values 104 according to a standard wireless protocol, such as 5G, BLUETOOTH, BLE, WiFi, 3G GPRS, 3G EVDO, 3G HSPA, 4G WiMAX, 4G E-UTRAN (LTE), etc. Although not all of the foregoing standards currently utilize LDPC, such as 3G and 4G, transmitter 103 includes configuration for multiple standard wireless protocols in at least some embodiments. In at least some embodiments, transmitter 103 is configured to transmit at a frequency and a timing scheme according to a standard wireless protocol. In at least some embodiments, transmitter 103 is configured to transmit binary values 104 through a data channel, and to transmit other information for decoding encoded data 102, such as information representing a parity-check matrix, through a control channel.

Receiver 106 is configured to receive probability values 105 through wireless reception, and to transmit encoded probability values 107 to decoder 108. In at least some embodiments, receiver 106 is configured to record probability values 105 in attempting to receive binary values 104, probability values 105 representing one or more probabilities of whether a received binary value represents a one or a zero from the transmission of binary values 104 as transmitted by transmitter 103. In at least some embodiments, receiver 106 records probability values having a confidence proportional to a signal-to-noise ratio during reception. In at least some embodiments, receiver 106 is configured to record more confident probability values during instances of higher signal-to-noise ratios, and less confident probability values during instances of lower signal-to-noise ratios. In at least some embodiments, the received values are represented as follows:

$${z}_{i} = {y}_{i} + {n}_{i} \qquad EQ . 1$$

where zᵢ represents the received values, yᵢ represents the transmitted values, nᵢ represents the Additive White Gaussian Noise (AWGN), and i is 1 to N, where N is the quantity of encoded probability values received. In at least some embodiments, receiver 106 converts the received values into the Log-Likelihood Ratio (LLR) domain as follows:

$$L L R ( {z}_{i} ) = log ( \frac{p ( {z}_{i} \vert {y}_{i} = 0 )}{p ( {z}_{i} \vert {y}_{i} = 1 )} ) \qquad EQ . 2$$

where p(zᵢ|yᵢ=0) is the probability that the received value is zero, and p(zᵢ|yᵢ=1) is the probability that the received value is one. In at least some embodiments, use of LLR values allows probability values to be added, and the absolute value of LLR indicates confidence of the probability.

In at least some embodiments, receiver 106 is configured to use multiple bits of data to record one or more probability values among probability values 105 corresponding to one binary value among binary values 104. In at least some embodiments, the number of bits of data used to record each probability value among probability values 105 depends on the hardware capabilities of receiver 106 or decoder 108. In at least some embodiments, receiver 106 is configured to use six bits of data to record one or more probability values among probability values 105 corresponding to one binary value among binary values 104. In at least some embodiments, receiver 106 is configured to receive probability values 105 in blocks of one or more predetermined lengths. In at least some embodiments, receiver 106 is configured to assemble probability values 105 into encoded probability values 107 using a format that clarifies correspondence between probability values among encoded probability values 107 and binary values among encoded data 102. In at least some embodiments, receiver 106 is configured to receive probability values 105 through a data channel, and to receive other information for decoding encoded data 102, such as information representing a parity-check matrix, through a control channel.

Decoder 108 is configured to receive encoded probability values 107 from receiver 106, and to output decoded data 109. In at least some embodiments, decoder 108 is configured to decode encoded probability values 107 into decoded data 109. In at least some embodiments, decoder 108 is configured to apply FEC decoding to encoded probability values 107 to produce decoded data 109. In at least some embodiments, decoder 108 is configured to apply LDPC decoding to encoded probability values 107 to produce decoded data 109. In at least some embodiments, decoder 108 is an integrated circuit, such as an FPGA, ASIC, etc. In at least some embodiments, decoder 108 is a computer having a processor and a memory storing instructions for execution by the processor.

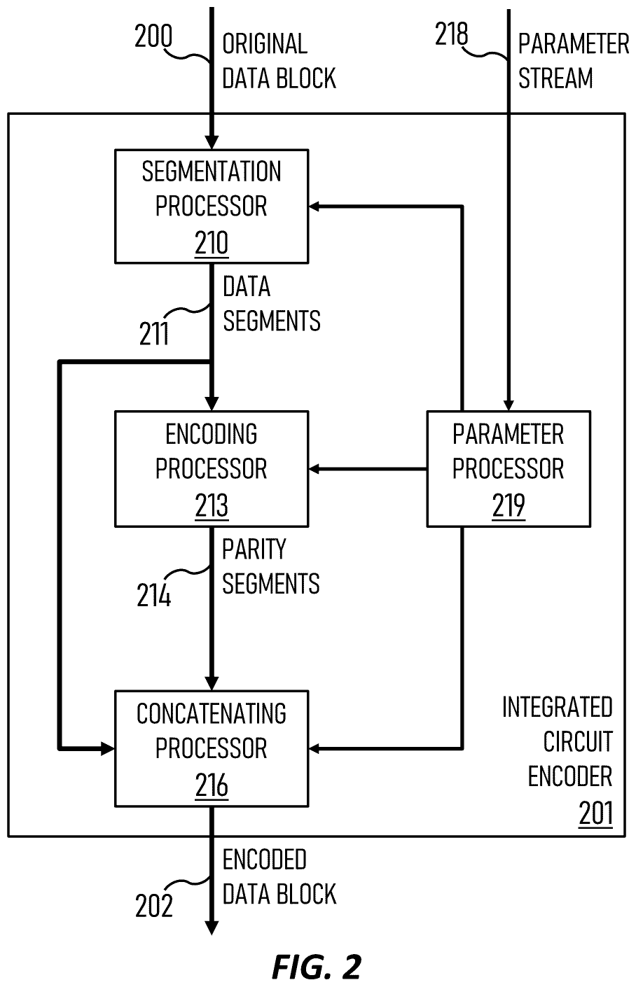

FIG. 2 is a schematic diagram of an integrated circuit encoder 201 for LDPC data encoding, according to at least one embodiment of the present invention. Integrated circuit encoder 201 includes segmentation processor 210, encoding processor 213, concatenating processor 216, and parameter processor 219.

Segmentation processor 210 is configured to receive original data block 200, and to transmit data segments 211 to encoding processor 213 and concatenating processor 216. In at least some embodiments, segmentation processor 210 is configured to divide an original block of data into a plurality of data segments. In at least some embodiments, segmentation processor 210 is configured to divide original data block 200 into segments of one or more predetermined lengths. In at least some embodiments, segmentation processor 210 is configured to divide original data block 200 into segments having a length according to the length of original data block 200. In at least some embodiments, segmentation processor 210 is configured to divide an original block of data into a plurality of data segments in accordance with columns of an LDPC base graph. In at least some embodiments, original data block 200 corresponds to an “information block” in the 5G standard, the information block being the result of prior segmentation, which is not performed by segmentation processor 210, of a transport block.

Encoding processor 213 is configured to receive data segments 211, and to transmit parity segments 214 to concatenating processor 216. In at least some embodiments, encoding processor 213 is configured to apply a parity-check matrix to data segments 211 to produce parity segments 214. In at least some embodiments, encoding processor 213 is configured to apply an LDPC parity-check matrix to data segments 211 to produce parity segments 214. In at least some embodiments, encoding processor 213 is configured to apply one or more circular shifts to each data segment 211 according to the parity-check matrix to produce parity segments 214. In at least some embodiments, encoding processor 213 is configured to apply one or more circular shifts to some parity segments, such as “core” parity segments, among parity segments 214 according to the parity-check matrix to produce other parity segments among parity segments 214. In at least some embodiments, encoding processor 213 is configured to populate each bit of each parity segment with values such that a sum total of the bit and binary values in a subset of values of one or more data segments and other parity segments corresponding to the bit is even.

Concatenating processor 216 is configured to receive data segments 211 and parity segments 214, and to output encoded data block 202. In at least some embodiments, concatenating processor 216 is configured to concatenate data segments 211 with parity segments 214 to produce encoded data block 202. In at least some embodiments, concatenating processor 216 is configured to concatenate data segments 211 with parity segments 214 into a format that clarifies correspondence between subsets of values of data segments 211 and parity segments 214.

Parameter processor 219 is configured to receive parameter stream 218, and transmit information to segmentation processor 210, encoding processor 213, and concatenating processor 216. In at least some embodiments, parameter processor 219 is configured to receive parameter stream 218 through a control channel. In at least some embodiments, parameter processor 219 is configured to receive information representing a parity-check matrix corresponding to original data block 200 within parameter stream 218. In at least some embodiments, parameter processor 219 is configured to transmit relevant parameters to each of segmentation processor 210, encoding processor 213, and concatenating processor 216. In at least some embodiments, parameter processor 219 is configured to transmit information representing a segment size to segmentation processor 210. In at least some embodiments, parameter processor 219 is configured to transmit information representing the parity-check matrix corresponding to original data block 200 to encoding processor 213. In at least some embodiments, parameter processor 219 is configured to transmit information representing the parity-check matrix corresponding to original data block 200 to concatenating processor 216.

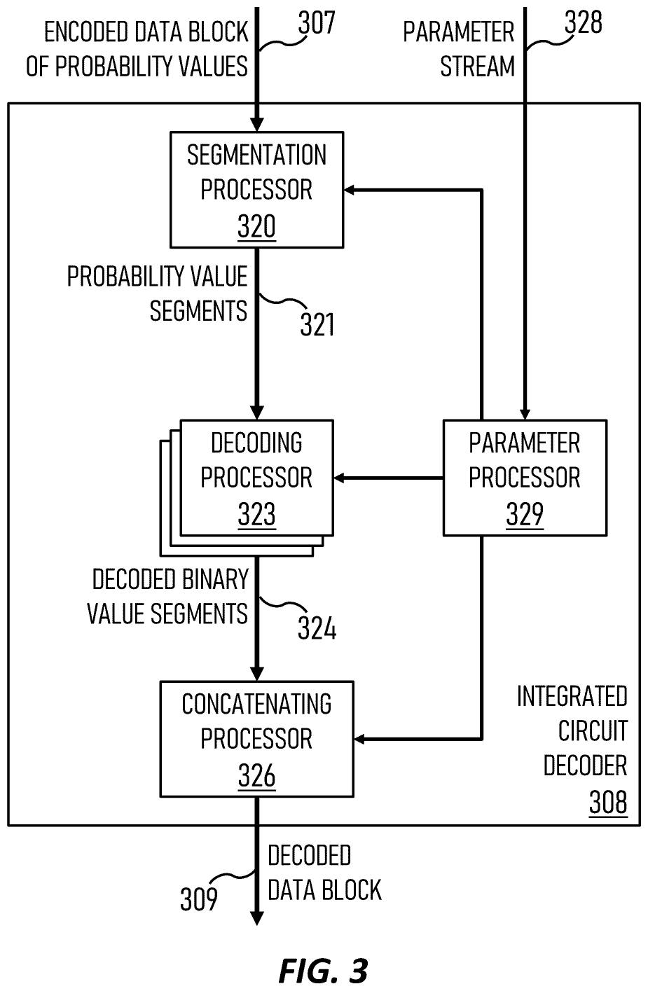

FIG. 3 is a schematic diagram of an integrated circuit decoder 308 for LDPC data decoding, according to at least one embodiment of the present invention. Integrated circuit decoder 308 includes segmentation processor 320, one or more decoding processors 323, concatenating processor 326, and parameter processor 329.

Segmentation processor 320 is configured to receive encoded data block of probability values 307, and to transmit probability value segments 321 to decoding processors 323. In at least some embodiments, probability value segments 321 includes data probability value segments and parity probability value segments. In at least some embodiments, segmentation processor 320 is configured to divide an encoded data block of probability values into a plurality of data probability value segments and a plurality of parity probability value segments, each probability value of the encoded data block representing a likelihood between binary values. In at least some embodiments, segmentation processor 320 is configured to divide encoded data block of probability values 307 into segments of one or more predetermined lengths. In at least some embodiments, segmentation processor 320 is configured to divide encoded data block of probability values 307 into segments having a length according to the length of encoded data block of probability values 307.

Decoding processors 323 are each configured to receive probability value segments 321, and to transmit decoded binary value segments 324 to concatenating processor 326. In at least some embodiments, each decoding processor 323 is configured to adjust, according to an iteration-variable accuracy parameter, probability values of the encoded data block based on a parity-check matrix, the parity-check matrix defining correspondence among data probability value segments and parity probability value segments, wherein the iteration-variable accuracy parameter represents a tradeoff between accuracy and computational efficiency. In at least some embodiments, decoding processors 323 are each configured to apply a parity-check matrix to probability value segments 321 to produce decoded binary value segments 324. In at least some embodiments, decoding processors 323 are each configured to apply an LDPC parity-check matrix to probability value segments 321 to produce decoded binary value segments 324. In at least some embodiments, decoding processors 323 are each configured to apply one or more circular shifts to each data probability value segment and each parity probability value segment among probability value segments 321 according to the parity-check matrix to produce decoded binary value segments 324. In at least some embodiments, decoding processors 323 are each configured to compare binary values in a subset of values of corresponding data probability value segments and parity probability value segments to ensure that a sum total of the values is even. In at least some embodiments, each of decoding processors 323 includes a sorter for sorting probability values into segments and finding the minimum value(s), a calculator for calculating update values from the minimum value(s), a function selector for selecting the correct function for determining an adjustment amount based on the minimum value(s), and an accuracy parameter selector for selecting the iteration-variable accuracy parameter.

Concatenating processor 326 is configured to receive decoded binary value segments 324, and to output decoded data block 309. In at least some embodiments, concatenating processor 326 is configured to concatenate the likely binary values that satisfy the parity-check matrix associated with the probability values of each data probability value segment to form a decoded data block. In at least some embodiments, concatenating processor 326 is configured to concatenate decoded binary value segments 324 to produce decoded data block 309. In at least some embodiments, concatenating processor 326 is configured to concatenate decoded binary value segments 324 into a format identical to the original block of data.

Parameter processor 329 is configured to receive parameter stream 328, and transmit information to segmentation processor 320, decoding processors 323, and concatenating processor 326. In at least some embodiments, parameter processor 329 is configured to transmit a plurality of parameters to each of the segmentation processor, the decoding processor, and the concatenating processor, wherein the plurality of parameters corresponds to the encoded data block. In at least some embodiments, parameter processor 329 is configured to receive parameter stream 328 through a control channel. In at least some embodiments, parameter processor 329 is configured to receive information representing a parity-check matrix corresponding to encoded data block of probability values 307 within parameter stream 328. In at least some embodiments, parameter processor 329 is configured to transmit relevant parameters to each of segmentation processor 320, decoding processors 323, and concatenating processor 326. In at least some embodiments, parameter processor 329 is configured to transmit information representing a segment size to segmentation processor 320. In at least some embodiments, parameter processor 329 is configured to transmit information representing the parity-check matrix corresponding to encoded data block of probability values 307 to decoding processors 323. In at least some embodiments, parameter processor 329 is configured to transmit information representing the parity-check matrix corresponding to encoded data block of probability values 307 to concatenating processor 326.

In general, applying a parity-check matrix to data segments and probability value segments is implemented by multiplying the segment by a circulant permutation matrix (CPM). In LDPC encoding, hundreds of operations performed on data segments of bits may be required for each original data block. In LDPC decoding, hundreds of operations performed on probability value segments of multi-bit values, such as LLR values, may be required for each encoded data block.

Due to the specific structure of the parity-check matrix, these multiplication operations are replaceable by circular shift operations according to at least some embodiments of the subject disclosure. In at least some embodiments of the subject disclosure, the computational elements used for circular shift operations have greater performance per unit of size than computational elements that perform operations of multiplying segments by a CPM. In at least some embodiments, the number of sequential values of a segment, i.e.—the segment length, ranges from 2 to 384. In at least some embodiments, the magnitude of the circular shift operation, i.e.—the shift amount, ranges from 0 to one less than the segment length. In at least some embodiments, although a parity-check matrix may require a shift amount several times greater than the segment length, the practical shift amount will be the remainder when the shift amount is divided by the segment length. For example, if the shift amount is 25, and the segment length is 4, then dividing 25 by 4 yields 6 with a remainder of 1.

In at least some embodiments, each segment is stored in a memory block of a fixed capacity. In at least some embodiments, the fixed capacity is the maximum segment length for a given application. In at least some embodiments, the fixed capacity for an LDPC application is 384 bits for a data segment, and 384 times the bit-width of an LLR value for a probability value segment. In at least some embodiments, data segments and probability value segments of less than the maximum segment length are stored in memory blocks having a fixed capacity corresponding to the maximum segment length. In at least some embodiments, a circular shift of a given shift amount is performed differently depending on the segment length. In at least some embodiments, a forward shift and a reverse shift are performed independently, and the results combined based on a mask to perform a circular shift. In at least some embodiments, a large multiplexor for CPM operations is not necessary. In at least some embodiments, the sequence of operations of a circular shift are pipelined to achieve a desired frequency. In at least some embodiments, circular shifts are scalable from maximum segment length to minimum segment length.

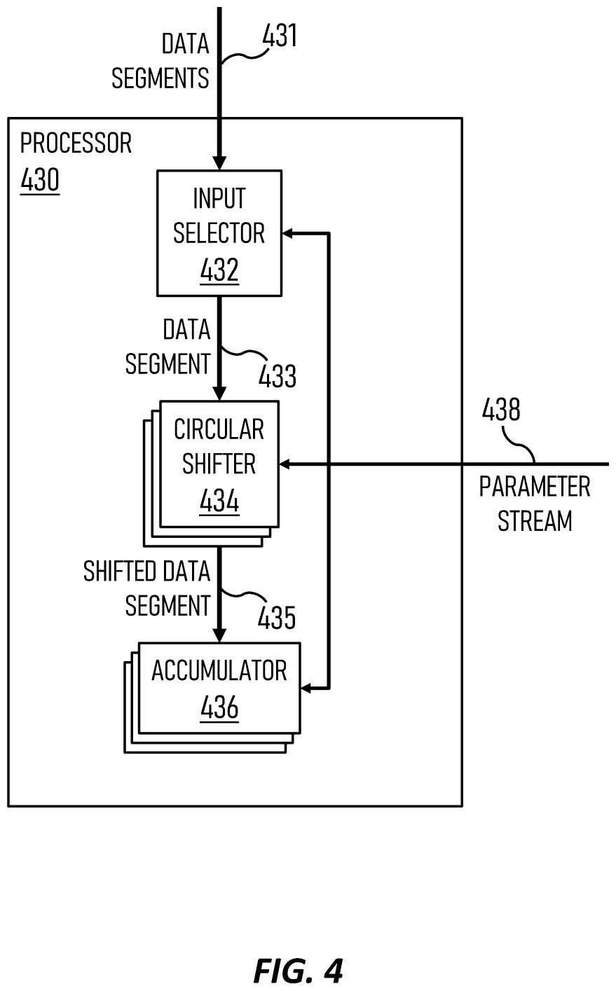

FIG. 4 is a schematic diagram of a processor utilizing shifter implemented circulant permutation matrix operations, according to at least some embodiments of the present invention. Processor 430 includes an input selector 432, one or more circular shifters 434, and one or more accumulators 436.

Input selector 432 is configured to receive data segments 431 and parameter stream 438, and to transmit data segment 433 to circular shifter 434. In at least some embodiments, input selector 432 is configured to receive data segments 431 from a segmentation processor, such as segmentation processor 210 of FIG. 2. In at least some embodiments, input selector 432 is configured to select data segment 433 from among data segments 431 for further processing. In at least some embodiments, input selector 432 is configured to receive parameter stream 438 from a parameter processor, such as parameter processor 219 of FIG. 2. In at least some embodiments, input selector 432 is configured to perform operations in accordance with parameter stream 438.

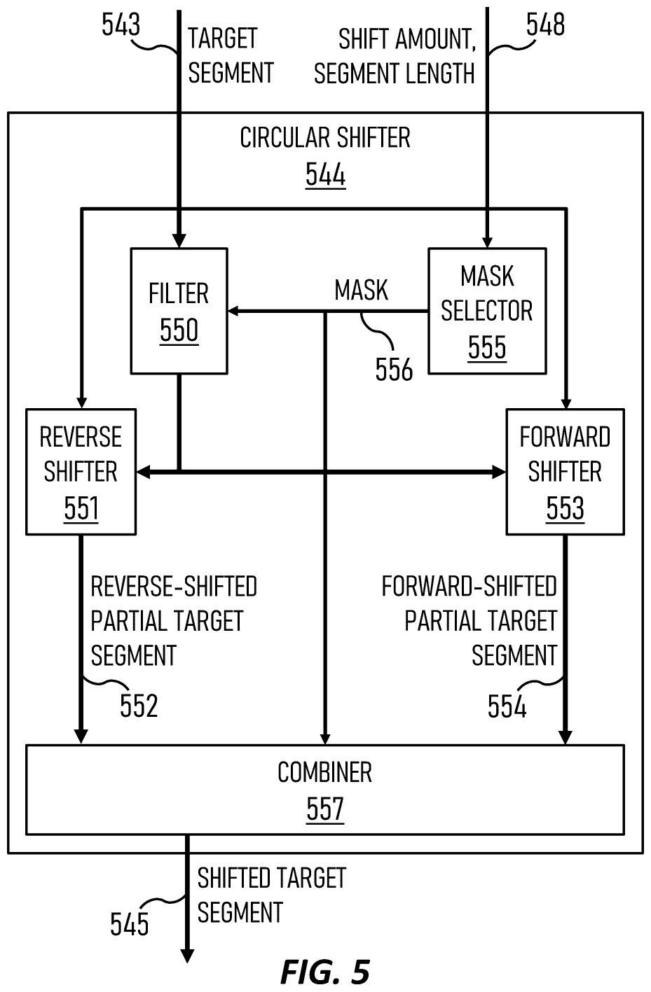

Circular shifters 434 are each configured to receive data segment 433 from input selector 432, and to transmit shifted data segment 435 to accumulator 436. In at least some embodiments, each circular shifter 434 is configured to apply a circular shift to data segment 433 to produce shifted data segment 435. In at least some embodiments, each circular shifter 434 is configured to receive parameter stream 438 from a parameter processor, such as parameter processor 219 of FIG. 2. In at least some embodiments, each circular shifter 434 is configured to perform operations in accordance with parameter stream 438. In at least some embodiments, more than one circular shifter 434 is used to parallelize shifting operations. In at least some embodiments, each circular shifter 434 includes a configuration of FIG. 5, described hereinafter.

Accumulators 436 are each configured to receive shifted data segment 435 from one among circular shifters 434, and to transmit shifted data segments downstream. In at least some embodiments, each accumulator 436 is configured to accumulate parity bits to produce parity segments. In at least some embodiments, each accumulator 436 is configured to accumulate statistics for updating probability values to produce decoded binary value segments. In at least some embodiments, the number of accumulators 436 is equal to the number of circular shifters 434. In at least some embodiments, each accumulator 436 is configured to receive parameter stream 438 from a parameter processor, such as parameter processor 219 of FIG. 2. In at least some embodiments, each accumulator 436 is configured to perform operations in accordance with parameter stream 438.

In at least some embodiments, processor 430 includes further computational elements for pre-processing data segments 431, post-processing output from accumulators 436, distributing parameters of parameter stream 438, etc. In at least some embodiments, processor 430 is an encoding processor, such as encoding processor 213 of FIG. 2. In at least some embodiments, an encoding processor utilizes a plurality of circular shifters, each circular shifter applying a circular shift to one probability value segment among the one or more probability value segments. Although FIG. 4 is shown processing data segments 431, in at least some embodiments, processor 430 is configured to process probability value segments, such as probability value segments 321 of FIG. 3. In at least some embodiments, processor 430 is a decoding processor, such as decoding processor 323 of FIG. 3. In at least some embodiments, multiple decoding processors operate in parallel, each decoding processor utilizing a single circular shifter.

FIG. 5 is a schematic diagram of circular shifter utilizing shifter implemented circulant permutation matrix operations, according to at least some embodiments of the present invention. Circular shifter 544 includes a filter 550, a reverse shifter 551, a forward shifter 553, a mask selector 555, and a combiner 557.

Filter 550 is configured to receive target segment 543 and mask 556, and to transmit target segment 543 to reverse shifter 551 and forward shifter 553. In at least some embodiments, filter 550 is configured to direct each sequential value of target segment 543 to an input of reverse shifter 551 and forward shifter 553 that corresponds to a unmasked indicator in mask 556. In at least some embodiments, filter 550 is configured to discard values that are not part of target segment 543 according to mask 556, the result of which is still target segment 543, but without any values outside of the segment length, such as those left over from previous iterations. In at least some embodiments, filter 550 includes a plurality of multiplexers arranged in parallel. In at least some embodiments, filter 550 is configured to control the plurality of multiplexers according to mask 556 corresponding to the segment length among shift amount and segment length 548. In at least some embodiments, filter 550 is configured to control each multiplexer according to a corresponding one-bit flag of mask 556.

Reverse shifter 551 is configured to receive a target segment 543, and a shift amount and segment length 548, and to transmit reverse-shifted partial target segment 552 to combiner 557. In at least some embodiments, reverse shifter 551 includes a plurality of multiplexers arranged in layers. In at least some embodiments, reverse shifter 551 includes a cascade of parallel 2×1 multiplexers. In at least some embodiments, reverse shifter 551 is configured to control at least some of the multiplexers by a signal corresponding to shift amount and segment length 548. In at least some embodiments, reverse shifter 551 is configured to shift in reverse each sequential value of target segment 543 by a reverse shift value equal to a segment length minus the shift amount to produce reverse-shifted partial target segment 552. In at least some embodiments, reverse shifter 551 is configured to discard each sequential value of target segment 543 having an original position that is less than or equal to the reverse shift value from a reverse side. In at least some embodiments, reverse shifter 551 is configured to direct each remaining sequential value of target segment 543 to an input of combiner 557 that represents a position shifted in reverse by the reverse shift value from the original position of the remaining sequential value. In at least some embodiments, reverse shifter 551 is configured to perform a logical shift in reverse by the reverse shift value.

Forward shifter 553 is configured to receive a target segment 543, and at least a shift amount 548, and transmits forward-shifted partial target segment 554 to combiner 557. In at least some embodiments, forward shifter 553 includes a plurality of multiplexers arranged in layers. In at least some embodiments, forward shifter 553 includes a cascade of parallel 2×1 multiplexers. In at least some embodiments, forward shifter 553 is configured to control at least some of the multiplexers by a signal corresponding to shift amount and segment length 548. In at least some embodiments, forward shifter 553 is configured to shift forward each sequential value of target segment 543 by a shift amount to produce forward-shifted partial segment 554. In at least some embodiments, forward shifter 553 is configured to discard each sequential value of target segment 554 having an original position that is less than or equal to the shift amount from a forward side. In at least some embodiments, forward shifter 553 is configured to direct each remaining sequential value of target segment 554 to an input of combiner 557 that represents a position shifted forward by the shift amount from the original position of the remaining sequential value. In at least some embodiments, forward shifter 551 is configured to perform a logical shift forward by the shift value.

Mask selector 555 is configured to receive a shift amount and segment length 548, and transmits mask 556 to at least one of filter 550 and combiner 557. In at least some embodiments, mask selector 555 is configured to select mask 556 corresponding to at least one of the shift amount and the segment length 548. In at least some embodiments, mask selector 555 is a Look-Up Table (LUT). In at least some embodiments, mask selector 555 is configured to generate mask 556 based on a function of the shift amount and the segment length. In at least some embodiments, mask 556 is a merge mask including a string of forward position indicators at consecutive positions equal to the reverse shift value from a forward side, and reverse position indicators at consecutive positions equal to the shift amount from a forward position indicator closest to a reverse side. In at least some embodiments, mask 556 is a filter mask including a string of unmasked indicators at consecutive positions from a forward side equal to the segment length. In at least some embodiments, mask 556 is a string of one-bit indicators, i.e.—ones and zeros. In at least some embodiments, the forward position indicators are represented by zeros and the reverse position indicators are represented by ones. In at least some embodiments, the unmasked indicators are represented by ones and the remainder of the string is represented by zeros.

Combiner 557 is configured to receive reverse-shifted partial target segment 552, forward-shifted partial target segment 554, and to transmit shifted target segment 545. In at least some embodiments, combiner 557 is configured to combine forward-shifted partial target segment 554 with reverse-shifted partial target segment 552 according to mask 556 to produce shifted target segment 545. In at least some embodiments, combiner 557 is configured to direct each sequential value of forward-shifted partial target segment 554 to an input of an accumulator, such as accumulator 436 of FIG. 4, that corresponds to a forward position indicator in mask 556. In at least some embodiments, combiner 557 is configured to direct each sequential value of reverse-shifted partial target segment 552 to an input of the accumulator that corresponds to a reverse position indicator in mask 556. In at least some embodiments, combiner 557 includes a plurality of multiplexers arranged in parallel. In at least some embodiments, combiner 557 controls the plurality of multiplexers by mask 556 corresponding to shift amount and segment length 548. In at least some embodiments, each multiplexer is controlled according to a corresponding one-bit flag of mask 556. In at least some embodiments, combiner 557 includes a plurality of OR gates arranged in parallel. In at least some embodiments, the plurality of OR gates are configured to combine forward-shifted partial target segment 554 with reverse-shifted partial target segment 552 to produce shifted target segment 545 without a merge mask. In at least some embodiments, the plurality of OR gates do not require a merge mask provided filter 550 applies a filter mask. In at least some embodiments, combiner 557 is configured to discard each sequential value of forward-shifted partial target segment 554 that lacks a corresponding forward position indicator in mask 556. In at least some embodiments, combiner 557 is configured to discard each sequential value of reverse-shifted partial target segment 554 that lacks a corresponding reverse position indicator in mask 556. In at least some embodiments, combiner 557 is further configured to perform the operations of filter 550 to filter shifted target segment 545 according to the filter mask.

In at least some embodiments, circular shifts are implemented in a clockwise direction, a counter-clockwise direction, or some other form, such as with respect to some other point of reference. In at least some embodiments, a shift forward is implemented as a shift to the right, and a shift in reverse is implemented as a shift to the left. In at least some embodiments, a shift forward is implemented as a shift to the left, and a shift in reverse is implemented as a shift to the right. In at least some embodiments, discarding of sequential values is performed by a passive action, or lack of action, such as ignoring sequential values. In at least some embodiments, discarding of a sequential value is realized by not directing the sequential value to an input of a subsequent stage of the pipeline. In at least some embodiments, discarding of sequential values is referred to as “shifting out” during a logical shift. In at least some embodiments, the mask selector is configured to selectively operate. In at least some embodiments, the mask selector is configured to, in response to receiving the shift amount and the segment length, transmit only a merge mask to the combiner, transmit only a filter mask to the filter, or transmit both a merge mask and a filter mask to the combiner. In at least some embodiments, the circular shifter does not include a filter, such as embodiments in which the combiner includes a plurality of multiplexers or embodiments in which the combiner also performs the operations of the filter.

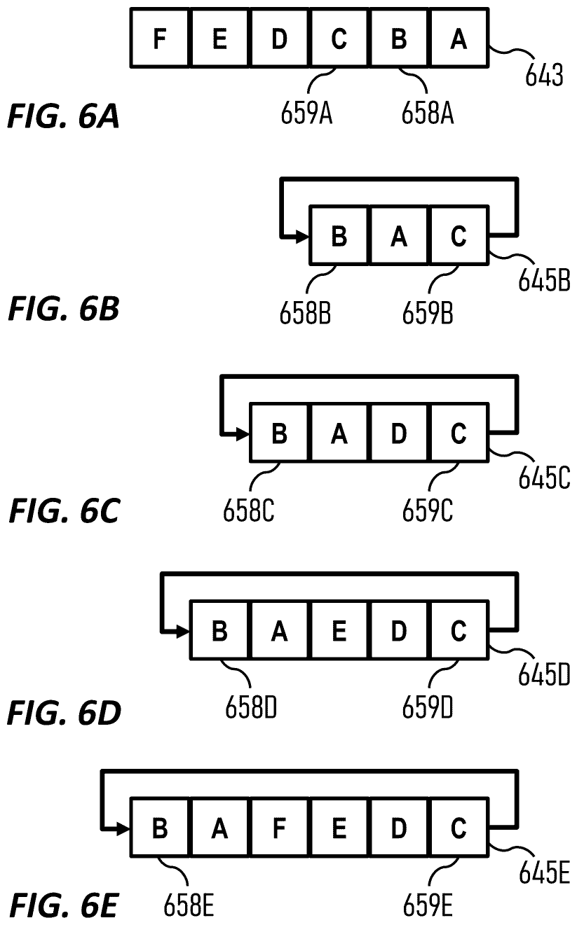

FIG. 6A is a diagram of original positions of a target segment, according to at least one embodiment of the present invention. Target segment 643 has a segment length of 6, and therefore includes 6 sequential values, indicated as A, B, C, D, E, and F, from the right side, which is the implementation of the forward side in this embodiment. Each sequential value is directed to an input that represents the original position of the sequential value. In at least some embodiments, each sequential value is directed by an input selector, such as input selector 432 of FIG. 4, to an input of a circular shifter, such as circular shifter 434 of FIG. 4, that represents the original position of the sequential value. For example, the sequential value indicated as “B” is directed to input 658A that represents the second position from the right side, and the sequential value indicated as “C” is direct to input 659A that represents the third position from the right side.

FIG. 6B is a diagram of a shifted target segment having a segment length of 3 and shifted by 2, according to at least one embodiment of the present invention. Shifted target segment 645B is the result of a circular shift of a target segment, such as target segment 643 but with only 3 sequential values, A, B, and C, from the right side. As a result of a shift amount of 2, the sequential value indicated as “C” occupies a new position that is shifted to the right by 2 positions from the original position of “C”. The sequential value indicated as “C” is directed to input 659B that represents the first position from the right side. In at least some embodiments, the sequential value indicated as “C” is directed to input 659B of an accumulator, such as accumulator 436 of FIG. 4, that represents the first position from the right side. As a result of a shift amount of 2, the sequential value indicated as “B” occupies a new position. The new position occupied by the sequential value indicated as “B” does not appear to be shifted to the right by 2 positions, but appears to be shifted to the left by 1 position. This is because in a circular shift a shift to a position beyond the first position to the right side is a shift to the first position on the left side. The sequential value indicated as “B” is directed to input 658B that represents the third position from the right side.

FIG. 6C is a diagram of a shifted target segment having a segment length of 4 and shifted by 2, according to at least one embodiment of the present invention. Shifted target segment 645C is the result of a circular shift of a target segment, such as target segment 643 but with only 4 sequential values, A, B, C, and D from the right side. As a result of a shift amount of 2, the sequential value indicated as “C” occupies a new position that is shifted to the right by 2 positions from the original position of “C”. The sequential value indicated as “C” is directed to input 659C that represents the first position from the right side. As a result of a shift amount of 2, the sequential value indicated as “B” occupies a new position that is equivalent to a shift to the right by 2 positions from the original position of “B”. The sequential value indicated as “B” is directed to input 658C that represents the fourth position from the right side.

FIG. 6D is a diagram of a shifted target segment having a segment length of 5 and shifted by 2, according to at least one embodiment of the present invention. Shifted target segment 645D is the result of a circular shift of a target segment, such as target segment 643 but with only 5 sequential values, A, B, C, D, and E from the right side. As a result of a shift amount of 2, the sequential value indicated as “C” occupies a new position that is shifted to the right by 2 positions from the original position of “C”. The sequential value indicated as “C” is directed to input 659D that represents the first position from the right side. As a result of a shift amount of 2, the sequential value indicated as “B” occupies a new position that is equivalent to a shift to the right by 2 positions from the original position of “B”. The sequential value indicated as “B” is directed to input 658D that represents the fifth position from the right side.

FIG. 6E is a diagram of a shifted target segment having a segment length of 6 and shifted by 2, according to at least one embodiment of the present invention. Shifted target segment 645D is the result of a circular shift of a target segment, such as target segment 643. As a result of a shift amount of 2, the sequential value indicated as “C” occupies a new position that is shifted to the right by 2 positions from the original position of “C”. The sequential value indicated as “C” is directed to input 659E that represents the first position from the right side. As a result of a shift amount of 2, the sequential value indicated as “B” occupies a new position that is equivalent to a shift to the right by 2 positions from the original position of “B”. The sequential value indicated as “B” is directed to input 658E that represents the sixth position from the right side.

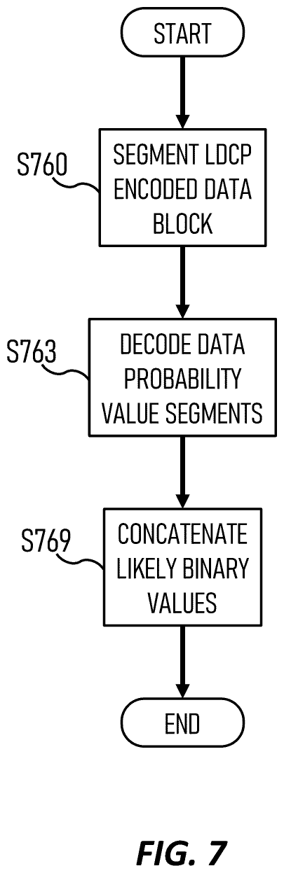

FIG. 7 is an operational flow for LDPC data decoding utilizing shifter implemented circulant permutation matrix operations, according to at least some embodiments of the present invention. The operational flow provides a method of LDPC data decoding utilizing shifter implemented circulant permutation matrix operations. In at least some embodiments, the method is performed by an integrated circuit, such as integrated circuit decoder 308 shown in FIG. 3.

At S760, a segmentation processor segments an LDCP encoded data block. In at least some embodiments, the segmentation processor segments a Low-Density Parity-Check (LDPC) encoded data block of probability values by dividing the encoded data block into a plurality of data probability value segments and a plurality of parity probability value segments, each probability value of the encoded data block representing a likelihood between binary values. In at least some embodiments, the segmentation processor divides the encoded data block into segments of one or more predetermined lengths. In at least some embodiments, the segmentation processor divides the encoded data block into segments having a length according to the length of the encoded data block.

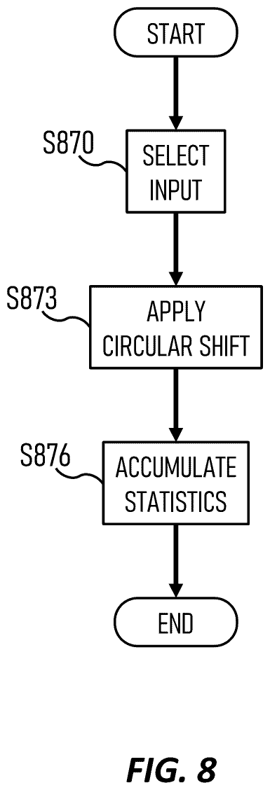

At S763, a decoding processor decodes the data probability value segments. In at least some embodiments, the decoding processor applies a parity-check matrix to the data probability value segments and the parity probability value segments to produce decoded binary value segments. In at least some embodiments, the decoding processor applies an LDPC parity-check matrix to the data probability value segments and the parity probability value segments to produce the decoded binary value segments. In at least some embodiments, the decoding processor applies one or more circular shifts to the data probability value segments and parity probability value segments according to the parity-check matrix to produce the decoded binary value segments. In at least some embodiments, the decoding processor compares binary values in a subset of values of corresponding data probability value segments and parity probability value segments to ensure that a sum total of the values is even. In at least some embodiments, the decoding processor decodes the encoded data block by adjusting, according to an iteration-variable accuracy parameter, probability values of the encoded data block based on a parity-check matrix, the parity-check matrix defining correspondence among data probability value segments and parity probability value segments, wherein the iteration-variable accuracy parameter represents a tradeoff between accuracy and computational efficiency. In at least some embodiments, the decoding processor performs the operational flow shown in FIG. 8, which will be explained hereinafter.

At S769, a concatenating processor concatenates likely binary values. In at least some embodiments, the concatenating processor concatenates the likely binary values that satisfy the parity-check matrix associated with the probability values of each data probability value segment to form a decoded data block. In at least some embodiments, the concatenating processor concatenates likely binary value segments to produce the decoded data block. In at least some embodiments, the concatenating processor concatenates likely binary value segments into a format identical to an original block of data.

FIG. 8 is an operational flow for data probability value segment decoding utilizing shifter implemented circulant permutation matrix operations, according to at least one embodiment of the present invention. The operational flow provides a method of data probability value segment decoding utilizing shifter implemented circulant permutation matrix operations. In at least some embodiments, the method is performed by an integrated circuit, such as integrated circuit decoder 308 shown in FIG. 3.

At S870, the decoder selects input. In at least some embodiments, the decoder selects one or more probability value segments from among probability value segments received from a segmentation processor, such as segmentation processor 321 of FIG. 3, for further processing. In at least some embodiments, the decoder utilizes an input selector to select input.

At S873, the decoder applies a circular shift. In at least some embodiments, the decoder applies a circular shift to the one or more probability value segments to produce shifted probability value segments. In at least some embodiments, the decoder utilizes a circular shifter to apply a circular shift to the one or more probability value segments. In at least some embodiments, the decoder utilizes a circular shifter to apply a circular shift to a probability value segment over multiple clock cycles by shifting a portion of sequential values of the probability value segment at each clock cycle. In at least some embodiments, shifting a portion of sequential values of the probability value segment enables utilization of a smaller shifter, which enables smaller circuit size.

At S876, the decoder accumulates statistics. In at least some embodiments, the decoder accumulates statistics for updating probability values to produce decoded binary value segments. In at least some embodiments, the decoder utilizes a circular shifter to accumulate statistics from the one or more shifted probability value segments. In at least some embodiments, the decoder utilizes a plurality of accumulators, each accumulator accumulating statistics from one shifted probability value segment among the one or more shifted probability value segments.

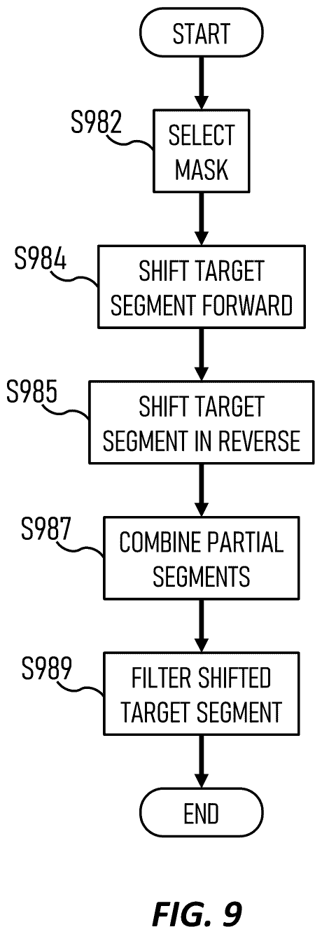

FIG. 9 is an operational flow for applying a shifter implemented circulant permutation matrix operation, according to at least one embodiment of the present invention. The operational flow provides a method of applying a shifter implemented circulant permutation matrix operation. In at least some embodiments, the method is performed by an circular shifter of an integrated circuit, such as circular shifter 544 shown in FIG. 5.

At S982, the circular shifter selects a mask. In at least some embodiments, the circular shifter selects the mask by utilizing a Look-Up Table (LUT). In at least some embodiments, the circular shifter selects, by a mask selector of the integrated circuit, a merge mask corresponding to the shift amount and the segment length. In at least some embodiments, the circular shifter generates the merge mask based on a function of the shift amount and the segment length. In at least some embodiments, the merge mask includes forward position indicators at consecutive positions equal to the reverse shift value from a forward side, and reverse position indicators at consecutive positions equal to the shift amount from a forward position indicator closest to a reverse side. In at least some embodiments, the circular shifter selects, by the mask selector, a filter mask corresponding to the segment length. In at least some embodiments, the filter mask includes unmasked position indicators at consecutive positions from a forward side equal to the segment length.

At S984, the circular shifter shifts a target segment forward. In at least some embodiments, the circular shifter shifts forward, by a forward shifter of an integrated circuit, each sequential value of a target segment by a shift amount to produce a forward-shifted partial target segment. In at least some embodiments, the circular shifter discards each sequential value of the target segment having an original position that is less than or equal to the shift amount from a forward side. In at least some embodiments, the circular shifter directs each remaining sequential value of the target segment to an input of a combiner, such as combiner 557 of FIG. 5, that represents a position shifted forward by the shift amount from the original position of the remaining sequential value.

At S985, the circular shifter shifts a target segment in reverse. In at least some embodiments, the circular shifter shifts in reverse, by a reverse shifter of the integrated circuit, each sequential value of the target segment by a reverse shift value equal to a segment length minus the shift amount to produce a reverse-shifted partial target segment. In at least some embodiments, the circular shifter discards each sequential value of the target segment having an original position that is less than or equal to the reverse shift value from a reverse side. In at least some embodiments, the circular shifter directs each remaining sequential value of the target segment to an input of the combiner that represents a position shifted in reverse by the reverse shift value from the original position of the remaining sequential value.

At S987, the circular shifter combines partial segments. In at least some embodiments, the circular shifter combines, by a combiner of the integrated circuit, the forward-shifted partial target segment with the reverse-shifted partial target segment to produce a shifted target segment. In at least some embodiments, the circular shifter directs each sequential value of the forward-shifted partial target segment to an input of an accumulator, such as accumulator 436 of FIG. 4, that corresponds to the shift amount and the segment length. In at least some embodiments, the circular shifter directs each sequential value of the reverse-shifted partial target segment to an input of the accumulator that corresponds to the shift amount and the segment length. In at least some embodiments, the circular shifter discards each sequential value of the forward-shifted partial target segment that do not correspond to the shift amount and the segment length. In at least some embodiments, the circular shifter discards each sequential value of the reverse-shifted partial target segment that do not correspond to the shift amount and the segment length. In at least some embodiments, the circular shifter combines, by a combiner of the integrated circuit, the forward-shifted partial target segment with the reverse-shifted partial target segment according to the merge mask to produce a shifted target segment. In at least some embodiments, the circular shifter directs each sequential value of the forward-shifted partial target segment to an input of an accumulator, such as accumulator 436 of FIG. 4, that corresponds to a forward position indicator in the merge mask. In at least some embodiments, the circular shifter directs each sequential value of the reverse-shifted partial target segment to an input of the accumulator that corresponds to a reverse position indicator in the merge mask. In at least some embodiments, the circular shifter discards each sequential value of the forward-shifted partial target segment that lacks a corresponding forward position indicator in the merge mask. In at least some embodiments, the circular shifter discards each sequential value of the reverse-shifted partial target segment that lacks a corresponding reverse position indicator in the merge mask.

At S989, the circular shifter filters the shifted target segment. In at least some embodiments, the circular shifter filters, by the combiner, the shifted target segment according to the filter mask. In at least some embodiments, the circular shifter directs each sequential value of the shifted target segment to an input of the accumulator that corresponds to an unmasked indicator in the filter mask. In at least some embodiments, the circular shifter discards values that are not part of the shifted target segment according to filter mask, the result of which is still the shifted target segment, but without any values outside of the segment length, such as those left over from previous iterations. In at least some embodiments, the circular shifter controls a plurality of multiplexers according to the filter mask corresponding to the segment length among shift amount and segment length 548. In at least some embodiments, the circular shifter controls each multiplexer according to a corresponding one-bit flag of mask 556.

In at least some embodiments of circular shift application, the circular shifter does not select a merge mask. In at least some embodiments of circular shift application, the circular shifter does not select a filter mask or filter the shifted target segment as filtering is optional. In at least some embodiments, the operations at S984 and S985 can be performed in any order, even at overlapping times or simultaneously as long as the operations at S984 and S985 are performed before the operation at S987. In at least some embodiments, the circular shifter filters, by a filter, the target segment before the target segment is shifted at S984 and S985.

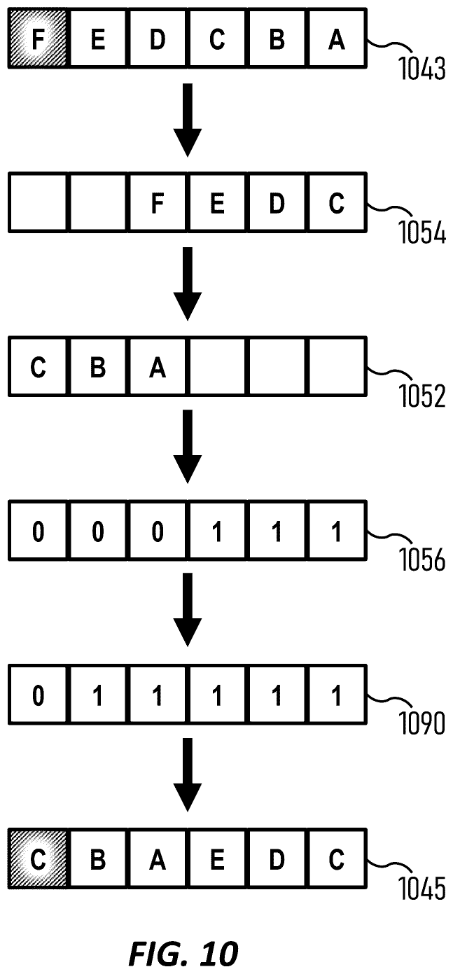

FIG. 10 is a diagram of a data segment undergoing a shifter implemented circulant permutation matrix operation having a shift amount of 2, according to at least one embodiment of the present invention. Target segment 1043 has a segment length of 5, and therefore includes 5 sequential values, indicated as A, B, C, D, and E, from the right side, which is the implementation of the forward side in this embodiment. Each sequential value is directed to an input that represents the original position of the sequential value. In at least some embodiments, each sequential value is directed by an input selector, such as input selector 432 of FIG. 4, to an input of a circular shifter, such as circular shifter 434 of FIG. 4, that represents the original position of the sequential value. In this embodiment, there are 6 inputs, which represents the maximum segment length of operations. In this embodiment, the value indicated as “F” is not part of target segment 1043, but 6 inputs are utilized in each operation of shifting to avoid the need for different hardware configurations or software instructions for each target segment length.

As a result of shifting target segment 1043 forward, such as the operation in S984 of FIG. 9, forward-shifted partial target segment 1054 is produced. During the operation, the values indicated as “A” and “B” are discarded because they occupy positions less than or equal to the shift amount, and the values indicated as “C”, “D”, “E”, and “F” are shifted forward by 2 positions. In at least some embodiments, each of the sequential values indicated as “C”, “D”, “E”, and “F” is directed by a forward shifter, such as forward shifter 553 of FIG. 5, to an input of a combiner, such as combiner 557 of FIG. 5, that represents a position shifted 2 positions forward from the original position of the sequential value. The value indicated as “F” is shifted regardless of the fact that this value is not part of target segment 1043.

As a result of shifting target segment 1043 in reverse, such as the operation in S985 of FIG. 9, reverse-shifted partial target segment 1052 is produced. During the operation, a reverse shift value equal to a segment length minus the shift amount is determined to be 3. During the operation, the values indicated as “D”, “E”, and “F” are discarded because they occupy positions less than or equal to the reverse shift value, and the values indicated as “A”, “B”, and “C” are shifted in reverse by 3 positions. In at least some embodiments, each of the sequential values indicated as “A”, “B”, and “C” is directed by a reverse shifter, such as reverse shifter 551 of FIG. 5, to an input of a combiner, such as combiner 557 of FIG. 5, that represents a position shifted 3 positions in reverse from the original position of the sequential value.

Optionally, as a result of mask selection, such as the operation in S982 of FIG. 9, merge mask 1056 is retrieved. Merge mask 1056 includes sequential indicators represented by “1” and “0”. The value represented by “1” is a forward position indicator. Forward position indicators occupy positions corresponding to sequential values of forward-shifted partial target segment 1054 that correctly occupy positions in shifted target segment 1045. The value represented by “0” is a reverse position indicator. Reverse position indicators occupy positions corresponding to sequential values of reverse-shifted partial target segment 1052 that correctly occupy positions in shifted target segment 1045. Positions in merge mask 1056 are indicated by binary indicators, and therefore positions intended to be left unoccupied are also represented by “0”, even though this is also the reverse position indicator. In at least some embodiments, the circular shifter is configured such that the value at positions intended to be left unoccupied is ignored, or is masked to zero before arriving at the shifters.

Optionally, as a result of mask selection, such as the operation in S982 of FIG. 9, filter mask 1090 is retrieved. Filter mask 1090 includes sequential indicators represented by “0” and “1”. In at least some embodiments, the sequential indicators are one-bit flags. The value represented by “0” is a masked position indicator. Masked position indicators occupy positions corresponding to unoccupied positions, or positions that are masked to zero, in shifted target segment 1045. The value represented by “1” is an unmasked position indicator. Unmasked position indicators occupy positions corresponding to occupied positions in shifted target segment 1045.

As a result of combining forward-shifted partial target segment 1054 and reverse-shifted partial target segment 1052 according to a shift amount of 2 and a segment length of 5, and optionally with one or both of merge mask 1056 and filter mask 1090, such as the operation in S987 of FIG. 9, shifted target segment 1045 is produced. The first position on the right side, or forward side, of shifted target segment 1045 is occupied by the value indicated as “C”, because the value indicated as “C” occupies the corresponding position in forward-shifted partial target segment 1054 and the corresponding position in merge mask 1056 is occupied by “F”, a forward position indicator. Similarly, each other position of shifted target segment 1045 is occupied by a value of a corresponding position in either forward-shifted partial target segment 1054 or reverse-shifted partial target segment 1052. In at least some embodiments, each of the sequential values is directed by a combiner, such as combiner 557 of FIG. 5, to an input of an accumulator, such as accumulator 4 of FIG. 4, that represents a position shifted 2 positions forward from the original position of the sequential value, according to a circular shift amount of 2 and a segment length of 5. Although the sixth position on the right side, or forward side, of shifted target segment 1045 corresponds to the value indicated as “C”, this value is not part of shifted target segment 1045.

In at least some embodiments, the apparatus is another device capable of processing logical functions in order to perform the operations herein. In at least some embodiments, the controller and the storage unit need not be entirely separate devices, but share circuitry or one or more computer-readable mediums in some embodiments. In at least some embodiments, the storage unit includes a hard drive storing both the computer-executable instructions and the data accessed by the controller, and the controller includes a combination of a central processing unit (CPU) and RAM, in which the computer-executable instructions are able to be copied in whole or in part for execution by the CPU during performance of the operations herein.

At least some embodiments are described with reference to flowcharts and block diagrams whose blocks represent (1) steps of processes in which operations are performed or (2) sections of a controller responsible for performing operations. In at least some embodiments, certain steps and sections are implemented by dedicated circuitry, programmable circuitry supplied with computer-readable instructions stored on computer-readable media, and/or processors supplied with computer-readable instructions stored on computer-readable media. In at least some embodiments, dedicated circuitry includes digital and/or analog hardware circuits and include integrated circuits (IC) and/or discrete circuits. In at least some embodiments, programmable circuitry includes reconfigurable hardware circuits comprising logical AND, OR, XOR, NAND, NOR, and other logical operations, flip-flops, registers, memory elements, etc., such as field-programmable gate arrays (FPGA), programmable logic arrays (PLA), etc.

In at least some embodiments, the computer readable storage medium includes a tangible device that is able to retain and store instructions for use by an instruction execution device. In some embodiments, the computer readable storage medium includes, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

In at least some embodiments, computer readable program instructions described herein are downloadable to respective computing/processing devices from a computer readable storage medium or to an external computer or external storage device via a network, for example, the Internet, a local area network, a wide area network and/or a wireless network. In at least some embodiments, the network includes copper transmission cables, optical transmission fibers, wireless transmission, routers, firewalls, switches, gateway computers and/or edge servers. In at least some embodiments, a network adapter card or network interface in each computing/processing device receives computer readable program instructions from the network and forwards the computer readable program instructions for storage in a computer readable storage medium within the respective computing/processing device.

In at least some embodiments, computer readable program instructions for carrying out operations described above are assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. In at least some embodiments, the computer readable program instructions are executed entirely on the user's computer, partly on the user's computer, as a stand-alone software package, partly on the user's computer and partly on a remote computer or entirely on the remote computer or server. In at least some embodiments, in the latter scenario, the remote computer is connected to the user's computer through any type of network, including a local area network (LAN) or a wide area network (WAN), or the connection is made to an external computer (for example, through the Internet using an Internet Service Provider). In at least some embodiments, electronic circuitry including, for example, programmable logic circuitry, field-programmable gate arrays (FPGA), or programmable logic arrays (PLA) execute the computer readable program instructions by utilizing state information of the computer readable program instructions to individualize the electronic circuitry, in order to perform aspects of the present invention.

While embodiments of the present invention have been described, the technical scope of any subject matter claimed is not limited to the above described embodiments. Persons skilled in the art would understand that various alterations and improvements to the above-described embodiments are possible. Persons skilled in the art would also understand from the scope of the claims that the embodiments added with such alterations or improvements are included in the technical scope of the invention.

The operations, procedures, steps, and stages of each process performed by an apparatus, system, program, and method shown in the claims, embodiments, or diagrams are able to be performed in any order as long as the order is not indicated by “prior to,” “before,” or the like and as long as the output from a previous process is not used in a later process. Even if the process flow is described using phrases such as “first” or “next” in the claims, embodiments, or diagrams, such a description does not necessarily mean that the processes must be performed in the described order.

In at least some embodiments, shifter implemented circulant permutation matrix operations are realized by an integrated circuit including a forward shifter configured to shift forward each sequential value of a target segment by a shift amount to produce a forward-shifted partial segment, a reverse shifter configured to shift in reverse each sequential value of the target segment by a reverse shift value equal to a segment length minus the shift amount to produce a reverse-shifted partial target segment, a combiner configured to combine the forward-shifted partial target segment with the reverse-shifted partial target segment according to the shift amount and the segment length to produce a shifted target segment, and a mask selector configured to select at least one of a merge mask corresponding to the shift amount and the segment length and a filter mask corresponding to the segment length.

The foregoing outlines features of several embodiments so that those skilled in the art would better understand the aspects of the present disclosure. Those skilled in the art should appreciate that this disclosure is readily usable as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that various changes, substitutions, and alterations herein are possible without departing from the spirit and scope of the present disclosure.

What is claimed is:

1. An integrated circuit comprising:
a forward shifter configured to shift forward each sequential value of a target segment by a shift amount to produce a forward-shifted partial segment;
a reverse shifter configured to shift in reverse each sequential value of the target segment by a reverse shift value equal to a segment length minus the shift amount to produce a reverse-shifted partial target segment;
a combiner configured to combine the forward-shifted partial target segment with the reverse-shifted partial target segment to produce a shifted target segment; and
a mask selector configured to select at least one of a merge mask corresponding to the shift amount and the segment length and a filter mask corresponding to the segment length.

2. The integrated circuit of claim 1, wherein the forward shifter is further configured to discard each sequential value of the target segment having an original position that is less than or equal to the shift amount from a forward side; and
direct each remaining sequential value of the target segment to an input of the combiner that represents a position shifted forward by the shift amount from the original position of the remaining sequential value.

3. The integrated circuit of claim 1, wherein the reverse shifter is further configured to discard each sequential value of the target segment having an original position that is less than or equal to the reverse shift value from a reverse side; and
direct each remaining sequential value of the target segment to an input of the combiner that represents a position shifted in reverse by the reverse shift value from the original position of the remaining sequential value.

4. The integrated circuit of claim 1, wherein the combiner is further configured to direct each sequential value of the forward-shifted partial target segment to an input that corresponds to the shift amount and the segment length;
direct each sequential value of the reverse-shifted partial target segment to an input that corresponds to the shift amount and the segment length.

5. The integrated circuit of claim 1, wherein the combiner is further configured to combine the forward-shifted partial target segment with the reverse-shifted partial target segment according to the merge mask.

6. The integrated circuit of claim 1, wherein the merge mask includes
forward position indicators at consecutive positions equal to the reverse shift value from a forward side, and
reverse position indicators at consecutive positions equal to the shift amount from a forward position indicator closest to a reverse side.

7. The integrated circuit of claim 1, further comprising:
a filter configured to filter the target segment according to the filter mask before the target segment is shifted forward and shifted in reverse.

8. The integrated circuit of claim 1, wherein the combiner is further configured to filter the shifted target segment according to the filter mask.

9. The integrated circuit of claim 1, wherein the filter mask includes unmasked position indicators at consecutive positions from a forward side equal to the segment length.

10. A method comprising:
shifting forward, by a forward shifter of an integrated circuit, each sequential value of a target segment by a shift amount to produce a forward-shifted partial target segment;
shifting in reverse, by a reverse shifter of the integrated circuit, each sequential value of the target segment by a reverse shift value equal to a segment length minus the shift amount to produce a reverse-shifted partial target segment;
combining, by a combiner of the integrated circuit, the forward-shifted partial target segment with the reverse-shifted partial target segment to produce a shifted target segment; and
selecting, by a mask selector of the integrated circuit, at least one of a merge mask corresponding to the shift amount and the segment length and a filter mask corresponding to the segment length.

11. The method of claim 10, wherein the shifting forward includes discarding each sequential value of the target segment having an original position that is less than or equal to the shift amount from a forward side; and
directing each remaining sequential value of the target segment to an input of the combiner that represents a position shifted forward by the shift amount from the original position of the remaining sequential value.

12. The method of claim 10, wherein the shifting in reverse includes discarding each sequential value of the target segment having an original position that is less than or equal to the reverse shift value from a reverse side; and
directing each remaining sequential value of the target segment to an input of the combiner that represents a position shifted in reverse by the reverse shift value from the original position of the remaining sequential value.

13. The method of claim 10, wherein the combining includes directing each sequential value of the forward-shifted partial target segment to an input that corresponds to the shift amount and the segment length;
directing each sequential value of the reverse-shifted partial target segment to an input that corresponds to the shift amount and the segment length.

14. The method of claim 10, wherein the forward-shifted partial target segment is combined with the reverse-shifted partial target segment according to the merge mask.

15. The method of claim 10, wherein the merge mask includes forward position indicators at consecutive positions equal to the reverse shift value from a forward side, and reverse position indicators at consecutive positions equal to the shift amount from a forward position indicator closest to a reverse side.

16. The method of claim 10, further comprising:
filtering, by a filter of the integrated circuit, the target segment according to the filter mask before the target segment is shifted forward and shifted in reverse.

17. The method of claim 10, further comprising selecting, by the mask selector, a filter mask; and
filtering, by the combiner, the shifted target segment according to the filter mask.

18. The method of claim 10, wherein the filter mask includes unmasked position indicators at consecutive positions from a forward side equal to the segment length.
